(19) United States
(12) Patent Application Publication
(10) Pub. No.: US 2020/0295236 A1
(43) Pub. Date: Sep. 17, 2020

(54) Method of Manufacturing an Optoelectronic Semiconductor Device and Optoelectronic Semiconductor Device

(71) Applicant: OSRAM OLED GmbH, Regensburg (DE)

(72) Inventors: Markus Pindl, Tegernheim (DE); Hailing Cui, Regensburg (DE)

(73) Assignee: OSRAM OLED GmbH, Regensburg (DE)

(21) Appl. No.: 16/642,846

(22) PCT Filed: Aug. 28, 2018
(86) PCT No.: PCT/EP2018/073083

§ 371 Date: Feb. 27, 2020

(30) Foreign Application Priority Data
Aug. 30, 2017 (DE) 10 2017 119 872.5

(51) Int. Cl. H01L 33/50; H01L 33/56

(52) U.S. Cl. CPC H01L 33/504; H01L 2933/0058; H01L 2933/0041; H01L 33/56

(57) ABSTRACT

A method for manufacturing an optoelectronic semiconductor device and an optoelectronic semiconductor device are disclosed. In an embodiment a method includes applying a photostructurable first photo layer on the radiation side of a semiconductor layer sequence, photostructuring the first photo layer, wherein holes are formed in the first photo layer in regions of first illumination areas, applying a first converter material to the structured first photo layer, wherein the first converter material partially or completely fills the holes, thereby forming first converter elements in the holes, the first converter elements covering the associated first illumination areas, removing the first photo layer; and applying a second converter material to the radiation side at least in regions of second illumination areas, the second illumination areas being different from the first illumination areas.

This patent application is a national phase filing under section 371 of PCT/EP2018/073083, filed Aug. 28, 2018, which claims the priority of German patent application 102017119872.5, filed Aug. 30, 2017, each of which is incorporated herein by reference in its entirety.

### TECHNICAL FIELD

A method of manufacturing an optoelectronic semiconductor device is provided. In addition, an optoelectronic semiconductor device is provided.

### SUMMARY OF THE INVENTION

Embodiments provide a method of manufacturing an optoelectronic semiconductor device in which different converter materials are applied to predetermined pixels of a semiconductor chip. Other embodiments provide an optoelectronic semiconductor device in which the color location of the emitted radiation can be continuously adjusted.

According to at least one embodiment, the method of manufacturing an optoelectronic semiconductor device comprises a step A) in which a semiconductor layer sequence is provided. The semiconductor layer sequence has a radiation side. The radiation side comprises a plurality of illumination areas.

The semiconductor layer sequence is based, for example, on a III-V compound semiconductor material. The semiconductor material is for example a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, where 0≤n≤1, 0≤m≤1 and m+n≤1 respectively. The semiconductor layer sequence may contain dopants as well as additional components. For the sake of simplicity, however, only the essential constituents of the crystal lattice of the semiconductor layer sequence, i.e., Al, As, Ga, In, N or P, are given, even if these may be partially replaced and/or supplemented by small amounts of other substances. Preferably the semiconductor layer sequence is based on AlInGaN.

The active layer of the semiconductor layer sequence contains in particular at least one pn junction and/or at least one quantum well structure and can, for example, generate electromagnetic radiation in the blue or green or red spectral range or in the UV range during normal operation. Preferably, the active layer generates UV radiation and/or blue light.

The semiconductor layer sequence can be provided in a wafer compound. The semiconductor layer sequence is preferably contiguous. For example, the semiconductor layer sequence comprises a contiguous active layer that extends over the entire lateral extent of the semiconductor chip. In particular, the semiconductor layer sequence is applied to a substrate. A single semiconductor chip with a semiconductor layer sequence as defined below can also be provided in step A).

The radiation side of the semiconductor layer sequence is in particular a main side of the semiconductor layer sequence.

The radiation side comprises a plurality of illumination areas. Each illumination area can be electrically controlled individually and independently of the other illumination areas, for example, on the finished component and during proper operation, and can emit electromagnetic radiation individually and independently of the other illumination areas. For example, each illumination area has an area of at least 1 μm² or at least 10 μm² or at least 100 μm². Alternatively or in addition, the area of each illumination area is at most 100000 μm² or 10000 μm² or 500 μm². The illumination areas are arranged in a matrix, for example. During the intended operation of the semiconductor layer sequence, unconverted radiation is preferably emitted from the semiconductor layer sequence via the illumination areas.

The illumination areas are therefore separate areas of the radiation side. For example, contact elements are applied on the radiation side or on a side of the semiconductor layer sequence facing away from the radiation side, whereby the contact elements can define the size and position of the illumination areas. The illumination areas are, for example, the projection of the contact elements onto the radiation side, whereby each contact element is then uniquely assigned an illumination area. However, trenches can also be or have been made in the semiconductor layer sequence to separate the illumination areas. The position and size of the individual illumination areas can also be determined by the process.

According to at least one embodiment, the method comprises a step B), in which a photostructurable first photo layer is applied to the radiation side. The first photo layer is preferably applied as a simply-connected layer over a plurality of illumination areas, in particular over all illumination areas or over the entire radiation side. The photo layer can, for example, be formed from a positive or negative photo material. The first photo layer can be distributed along the radiation side by spin coating or laminating. However, a dry photo material can also be used as the first photo layer, which is glued on.

According to at least one embodiment, the method comprises a step C) in which the first photo layer is photostructured. In this process, holes are formed in the first photo layer in the region of the first illumination areas.

A photolithographic process is used to create the holes in the first photo layer. The first photo layer is exposed in certain areas. The areas that are still soluble after exposure can then be rinsed away from the radiation side with a solvent, thus creating the holes. The exposure can be done, for example, by means of a mask or by a stepper process or by an LDI process (Laser Direct Imaging Process). However, it is also possible to control the individual illumination areas accordingly so that they emit radiation and expose the first photo layer at the desired locations. In this case, the material of the first photo layer is in particular a positive photo material.

The holes in the first photo layer created by structuring are located in the area of the first illumination areas. For example, each hole in the first photo layer is uniquely assigned to a first illumination area. Each hole is then laterally, i.e., in the direction parallel to the active layer, surrounded, in particular completely surrounded, by an edge or wall from the first photo layer. The lateral extension of each hole corresponds thereby preferably essentially to the lateral extension of the associated first illumination area. For example, seen in plan view on the radiation side, each hole in the first photo layer completely overlaps the associated first illumination area. In a top view of the radiation side, the areas of the holes and the associated first illumination areas differ, for example, by at most 20% or 10% or 5%.

For example, at least 20% or at least 40% of all illumination areas on the radiation side are first illumination areas over which holes are formed in the first photo layer. However, the size and position of the first illumination areas can also be defined only by the formation of the first holes.

According to at least one embodiment, the method comprises a step D) in which a first converter material is applied to the structured first photo layer. The first converter material partially or completely fills the holes. As a result, first converter elements are formed in the holes, which cover the associated first illumination areas.

The first converter material can comprise one or more phosphors. The phosphor(s) can be embedded in a matrix material. The phosphor(s) can be in the form of particles or molecules. The matrix material may, for example, comprise a polymer or silicone or resin or epoxy or consist of these.

The converter material can be laminated or sprayed on, for example. After applying the first converter material, it can be cured.

For example, the first converter elements cover at least 90% or at least 95% or at least 99% or completely of the associated first illumination areas.

According to at least one embodiment, the method comprises a step E) in which the first photo layer is removed from the radiation side. Thus, in particular, those areas of the first photo layer are removed which have not already been removed during the structuring process in step C). For example, another solvent can be used for this purpose.

According to at least one embodiment, the process comprises a step F) in which a second converter material is applied to the radiation side at least in the region of second illumination areas. The second illumination areas are preferably different from the first illumination areas. For example, a second illumination area is arranged immediately adjacent to each first illumination area.

For example, at least 20% or at least 40% of all illumination areas are second illumination areas. For example, the radiation side consists only of first illumination areas and second illumination areas.

Like the first converter material, the second converter material can comprise one or more phosphors. The phosphor(s) is/are for example in the form of particles or molecules. The phosphor(s) can be distributed and embedded in a matrix material.

The matrix material can be chosen like for the first converter material. The second converter material differs from the first converter material preferably by one phosphor or by several phosphors or by all phosphors.

The second converter material preferably covers the second illumination areas completely or to at least 90% or to at least 95% or to at least 99%.

In particular, the first converter material is configured to partially or completely convert a radiation of a first wavelength range emitted by the semiconductor layer sequence during operation into a radiation of a second wavelength range. The second converter material is preferably designed to partially or completely convert the radiation of the first wavelength range emitted by the semiconductor layer sequence into radiation of a third wavelength range. The first, second and third wavelength ranges are preferably different pairwise.

According to at least one embodiment, after steps A) to F) the first converter elements are in direct contact with the second converter material. In particular, the first converter elements are in direct contact with the second converter material located on adjacent second illumination areas. Preferably, the first converter elements also remain in direct contact with the second converter material in the finished semiconductor device. The first converter elements are therefore not separated from the second converter material by trenches, barriers or intermediate layers. In particular, the process involves applying the second converter material directly to the first converter material or vice versa.

Alternatively, however, it is also possible that the first converter elements are separated from the second converter material by partitions, especially reflective partitions.

In at least one embodiment, the method for producing an optoelectronic semiconductor device comprises a step A) in which a semiconductor layer sequence is provided, the semiconductor layer sequence having a radiation side with a plurality of illumination areas. In a step B), a photostructurable first photo layer is applied to the radiation side. In a step C), the first photo layer is photostructured, wherein holes are formed in the first photo layer in the region of first illumination areas. In a step D), a first converter material is applied to the structured first photo layer, the first converter material partially or completely filling the holes, thereby creating first converter elements in the holes which cover the assigned first illumination areas. In step E) the first photo layer is removed. In a step F) a second converter material is applied to the radiation side at least in the region of second illumination areas which are different from the first illumination areas. After steps A) to F) the first converter elements are in direct contact with the second converter material.

Embodiments of the present invention are based on the idea of specifying a method by which individual pixels or illumination areas of a semiconductor layer sequence can be coated with different converter materials so as to produce a semiconductor device in which the colour location of the emitted radiation is continuously adjustable. The illumination areas are preferably so small that they are not perceptible to the naked eye by an observer. The observer therefore only sees mixed radiation coming from different illumination areas, but cannot perceive that radiation of different colours comes from different illumination areas. With the specified process, even very small illumination areas can be coated with a converter material independently of the neighbouring illumination areas.

According to at least one embodiment, steps B) to E) are carried out one after the other and in the specified order. For example, step F) can be carried out before step B) or after step E).

According to at least one embodiment, the semiconductor layer sequence is separated into a plurality of pixelated semiconductor chips after steps E) and F). Each semiconductor chip then comprises a part of the semiconductor layer sequence and a part of the radiation side including the first and second illumination areas. For example, each semiconductor device comprises exactly one such semiconductor chip.

Here and in the following, a semiconductor chip is understood to be an element that can be handled separately and can be electrically contacted. A semiconductor chip results in particular from the separation of a semiconductor layer sequence grown on a growth substrate. A semiconductor chip preferably comprises exactly one originally connected region of the grown semiconductor layer sequence. The semiconductor layer sequence of the semiconductor chip is preferably formed contiguously. The semiconductor chip comprises a contiguous or a segmented active layer. The lateral extension of the semiconductor chip, measured parallel to the main extension direction of the active layer, is for example at most 1% or at most 5% larger than the lateral extension of the active layer. The semiconductor chip also includes, for example, the growth substrate on which the entire semiconductor layer sequence has grown.

A pixelated semiconductor chip is a semiconductor chip whose radiation side is divided into a plurality of individual pixels or illumination areas. In particular, the semiconductor chip is set up in such a way that each of these illumination areas can be controlled individually and independently of the other illumination areas and then emits electromagnetic radiation individually and independently of the other illumination areas. For example, the semiconductor chip comprises at least 16 or at least 100 or at least 2500 such illumination areas.

According to at least one embodiment, the first photo layer comprises a photostructurable silicone or consists of a photostructurable silicone. Photostructurable silicones are known to the person of skill in the art. The photostructurable silicone may contain phosphors.

The inventors have found out that photostructurable silicones are particularly advantageous for the production of small converter elements for pixelated semiconductor chips. One reason for this is that photostructurable silicones have a very low modulus of elasticity. This allows the first photo layer to be removed in step E) without the risk of damaging the resulting first converter elements.

Moreover, silicone adheres very well to the radiation side. If, for example, the semiconductor layer sequence is heated during the method of manufacturing, the lateral expansion of the radiation side or of the individual illumination areas changes. This change in lateral expansion can easily be transferred to the first photo layer due to the low modulus of elasticity of silicone and the high adhesive strength on the radiation side, so that the risk of fractures in the first photo layer during the method is reduced.

According to at least one embodiment, the first converter material is removed from regions laterally adjacent to the holes before or during step E). In particular, the first converter material thus remains only in the form of the first converter elements in the region of the first illumination areas. In the finished semiconductor device, for example, the second illumination areas are essentially free of the first converter material. “Essentially free” here means, for example, that after step E) at most 5% or at most 1% of the areas of the second illumination areas are covered by the first converter material.

Before step E), the first converter material located on the first photo layer can be ground off, for example, or removed by a lift-off process.

According to at least one embodiment of the method, step F) is executed after steps A) to E). This means in particular that the second converter material is applied to the radiation side after the first converter material.

According to at least one embodiment of the method, the second converter material is applied to a plurality of illumination areas, wherein the first illumination areas already covered with the first converter elements are also covered. In the region of the second illumination areas, the second converter material is applied directly to the radiation side, for example.

According to at least one embodiment, the second converter material is applied directly to the first converter elements in the region of the first illumination areas. No further material is therefore placed between the first converter elements and the second converter material.

According to at least one embodiment, a photostructurable second photo layer is applied to the radiation side in step F). Subsequently, the second photo layer is photostructured in such a way that holes are created in the region of the second illumination areas. The second converter material is then applied to the structured second photo layer, whereby the second converter material partially or completely fills the holes and second converter elements are created in the holes of the second photo layer, which cover the assigned second illumination areas.

The second photo layer may comprise or consist of the same materials as the first photo layer. The second photo layer can be applied using the same processes as the first photo layer. The structuring of the second photo layer can be done in the same way as the structuring of the first photo layer. All information given with regard to the holes in the structured first photo layer and the associated first illumination areas, in particular with regard to their lateral extensions, can apply analogously to the holes in the second photo layer and the second illumination areas associated with these holes.

Preferably, the second photo layer is applied directly to the first converter elements in the region of the first illumination areas and/or directly to the radiation side in the region of the second illumination areas.

According to at least one embodiment, the second converter elements directly adjoin the first converter elements. In particular, the first converter elements and the second converter elements form platelets which are adjacent to each other on the radiation side and touch each other.

Alternatively, however, it is also possible that the first converter elements are spaced from the second converter elements by partitions, in particular reflective partitions. The partitions preferably remain in the finished semiconductor device.

The first and/or second illumination areas can each have a rectangular or square or hexagonal geometrical shape when viewed from above on the radiation side. The first and/or second converter elements are preferably also rectangular or square or hexagonal in plan view. This is achieved, for example, by making the holes in the first and/or second photo layer rectangular or square or hexagonal. Preferably, each first converter element, seen in plan view, borders with one edge of the rectangle or square or hexagon on an edge of the rectangle or square or hexagon of a second converter element.

The first and the second illumination areas are preferably arranged in a regular pattern, in particular periodically and/or alternately. For example, the first and second illumination areas are arranged in the form of a matrix. Preferably, the first and second converter elements follow this pattern.

According to at least one embodiment, step F) is carried out before steps B) to E). This means that the second converter material is applied to the radiation side before the first photo layer and the first converter material are applied.

According to at least one embodiment, the second converter material is applied as a simply-connected layer on the radiation side. The layer of the second converter material covers the first illumination areas and the second illumination areas. For example, all illumination areas on the radiation side are covered by the layer of the second converter material. Preferably, the layer of the second converter material is applied directly to the first and second illumination areas. A side of the layer of the first converter material facing away from the radiation side is then preferably flat over its entire lateral extent within the scope of the manufacturing tolerance.

According to at least one embodiment, the radiation side comprises third illumination areas. The third illumination areas are preferably different from both the first illumination areas and the second illumination areas. For example, at least 20% of all illumination areas are third illumination areas. For example, the radiation side consists only of first, second and third illumination areas.

According to at least one embodiment, the third illumination areas are kept free from the first converter material and the second converter material. In this way, for example, an RGB emitter can be realized. In the finished semiconductor device, the third illumination areas are thus essentially free of the first converter material and the second converter material. This means, for example, that at most 5% or 1% of the areas of the third illumination areas are covered by the first and second converter material.

In addition, an optoelectronic semiconductor device is specified. The optoelectronic semiconductor device may be manufactured in particular by the method described herein. This means that all features disclosed in connection with the method are also disclosed for the optoelectronic semiconductor device and vice versa.

According to at least one embodiment, the optoelectronic semiconductor device comprises a pixelated semiconductor chip, the semiconductor chip having a radiation side with a plurality of illumination areas or pixels. The individual pixels or illumination areas are preferably individually and independently controllable.

During proper operation of the semiconductor device, for example, at least 50% or at least 80% of the total radiation emitted by the semiconductor chip is coupled out of the semiconductor chip via the radiation side.

According to at least one embodiment, the first illumination areas are covered by first converter elements made of a first converter material.

According to at least one embodiment, a first converter element is uniquely assigned to each of the first illumination areas. In particular, the first converter element assigned to a first illumination area covers at least 95% of the first illumination area and at most 5% of other illumination areas.

According to at least one embodiment, the optoelectronic semiconductor device comprises a second converter material which is different from the first converter material. The second converter material covers second illumination areas which are different from the first illumination areas.

According to at least one embodiment form, the second converter material directly adjoins the first converter elements. In particular, the first converter elements are in direct contact with the second converter material located on adjacent second illumination areas.

According to at least one embodiment, the second converter material is laid over a plurality of first illumination areas and second illumination areas as a simply-connected layer. For example, the layer of the second converter material covers a large part, i.e., at least 50% or at least 80% of all illumination areas or pixels of the semiconductor chip.

According to at least one embodiment, the layer of the second converter material is arranged between the semiconductor chip and the first converter elements in the region of the first illumination areas. The first converter elements lie, for example, directly on the layer of the second converter material.

According to at least one embodiment form, the second converter material is additionally applied to the first converter elements, so that the first converter elements are arranged between the semiconductor chip and the second converter material. In this case, the second converter material can also be applied as a simply-connected layer on the first and second illumination areas. Alternatively, it is possible that the second converter material forms a layer on each of the first converter elements which is not contiguous with the layers of the second converter material on the other first converter elements. The second converter material can again be applied to at least 50% or at least 80% of all illumination areas.

According to at least one embodiment, the second illumination areas are covered by second converter elements made of the second converter material. Preferably, a second converter element is uniquely assigned to each of the second illumination areas. This means that the second converter element assigned to a second illumination area covers at least 95% of the assigned second illumination area and all other illumination areas of the radiation side to at most 5%. The first illumination areas on which the first converter elements are arranged are then preferably covered by the second converter material to at most 5%.

Viewed from above on the radiation side, the first converter elements and the second converter elements lie, for example, next to each other and adjoin each other. The first converter elements and the second converter elements may have different thicknesses, measured perpendicular to the radiation side. Alternatively, the thicknesses of the first and second converter elements can also be the same within the manufacturing tolerance.

According to at least one embodiment, the semiconductor chip emits radiation of a first wavelength range during normal operation. The radiation of the first wavelength range is preferably radiation in the blue spectral range, for example, with an intensity maximum between 430 nm and 480 nm inclusive. The semiconductor chip is then, for example, an AlInGaN-based semiconductor chip.

According to at least one embodiment form, the first converter material and the second converter material are selected in such a way that radiation emerging from the semiconductor device in the region of the first illumination areas is warm white light and the radiation emerging from the semiconductor device in the region of the second illumination areas is cold white light.

For example, the second converter material comprises a yellow phosphor, such as YAG:Cer. For example, the first converter material comprises a red phosphor such as an alkaline earth silicon nitride and/or alkaline earth aluminum silicon nitride doped with rare earths.

Cold white light in this case means in particular light with a colour temperature of at least 5300 K. Warm white light is understood to mean, in the present case, for example, light with a colour temperature of at most 3300 K. Depending on how many first illumination areas and second illumination areas in the semiconductor device are controlled, the colour or colour temperature of the total white light emitted can be adjusted continuously.

But it is also possible that the first converter material and the second converter material are chosen in a way that the radiation emerging in the region of the first illumination areas is cold white light and the radiation emerging in the region of the second illumination areas is warm white light. The above mentioned possible phosphors are then, for example, distributed exactly the other way round as indicated above to the two converter materials.

According to at least one embodiment, the semiconductor chip emits blue light during operation.

According to at least one embodiment, the first converter material is selected to convert blue light into green light. The first converter material is therefore a green converter. In particular, the first converter material is then applied so thickly to the first illumination areas that the radiation emerging from the first illumination areas is completely converted into green light. For example, the first converter material includes doped barium strontium silicon oxide as a phosphor, such as BaSrSiO₄:Eu.

According to at least one embodiment, the second converter material is selected to convert blue light into red light. The second converter material is therefore a red converter. In particular, the layer of the second converter material is applied so thickly to the second illumination areas that the radiation emerging from the second illumination areas is completely converted into red light. For example, the second converter material comprises an alkaline earth silicon nitride and/or alkaline earth aluminium silicon nitride doped with rare earths.

According to at least one embodiment, the semiconductor device has a radiation surface with a Bayer matrix. In particular, the semiconductor chip then comprises third illumination areas which are not covered by either the first converter material or the second converter material to more than 5%. Unconverted blue radiation can emerge from the semiconductor device in the region of these illumination areas. The radiation surface is formed, for example, by the radiation side with the converter materials applied to it.

### BRIEF DESCRIPTION OF THE DRAWINGS

An optoelectronic semiconductor device described herein as well as a method of manufacturing an optoelectronic semiconductor device described herein are explained in more detail below with reference to drawings on the basis of exemplary embodiments. Identical reference signs indicate identical elements in the individual figures. However, no scale references are shown; rather, individual elements may be shown in exaggerated size for better understanding.

In the figures:

FIGS. 1A to 3F show different embodiments of methods of manufacturing optoelectronic semiconductor devices in side view; and

FIGS. 4A to 4C show exemplary embodiments of optoelectronic semiconductor devices in top view of the radiation side.

### DETAILED DESCRIPTION OF ILLUSTRATIVE EMBODIMENTS

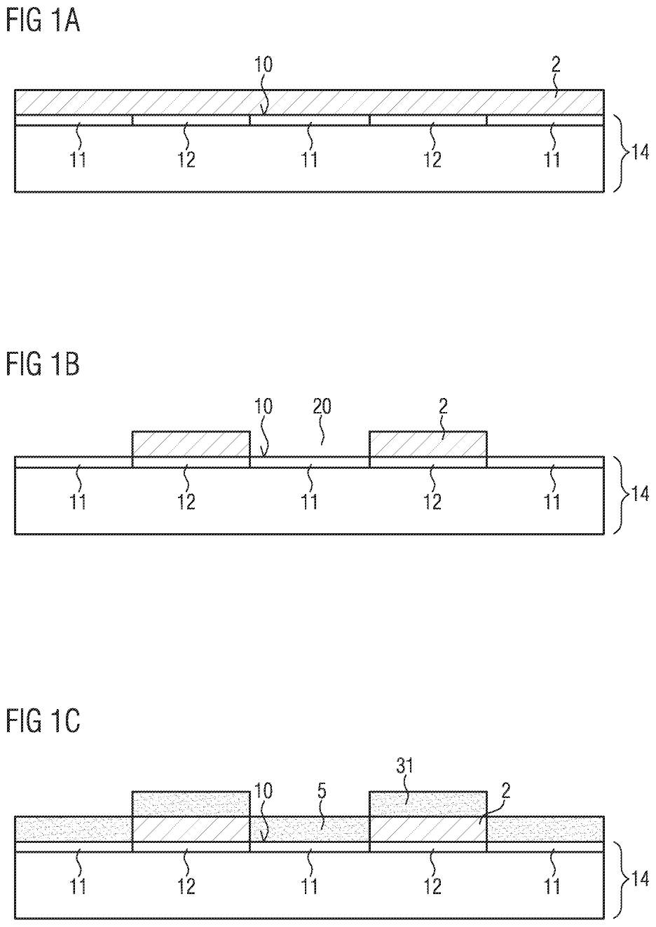

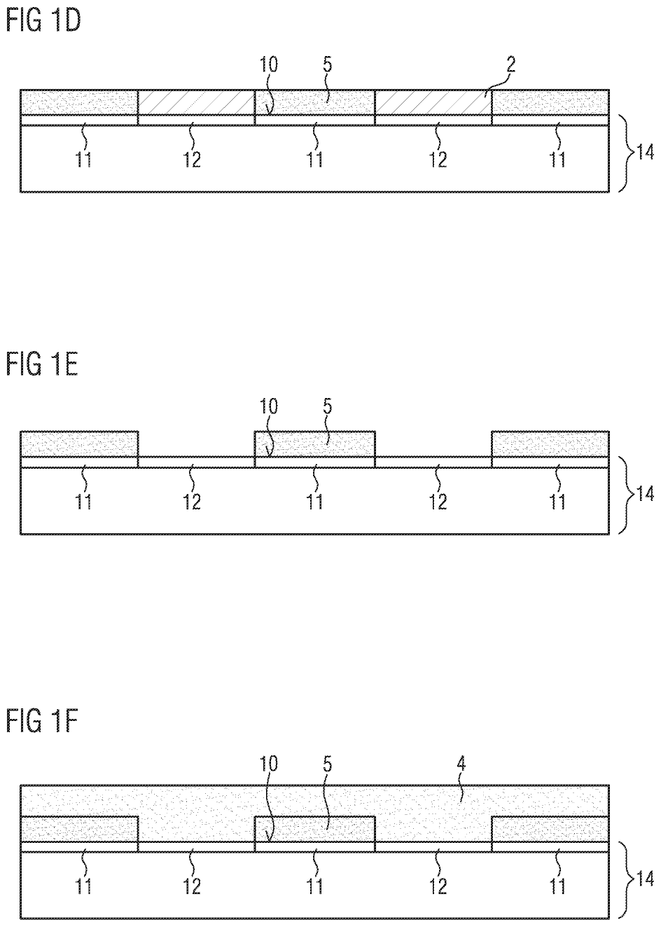

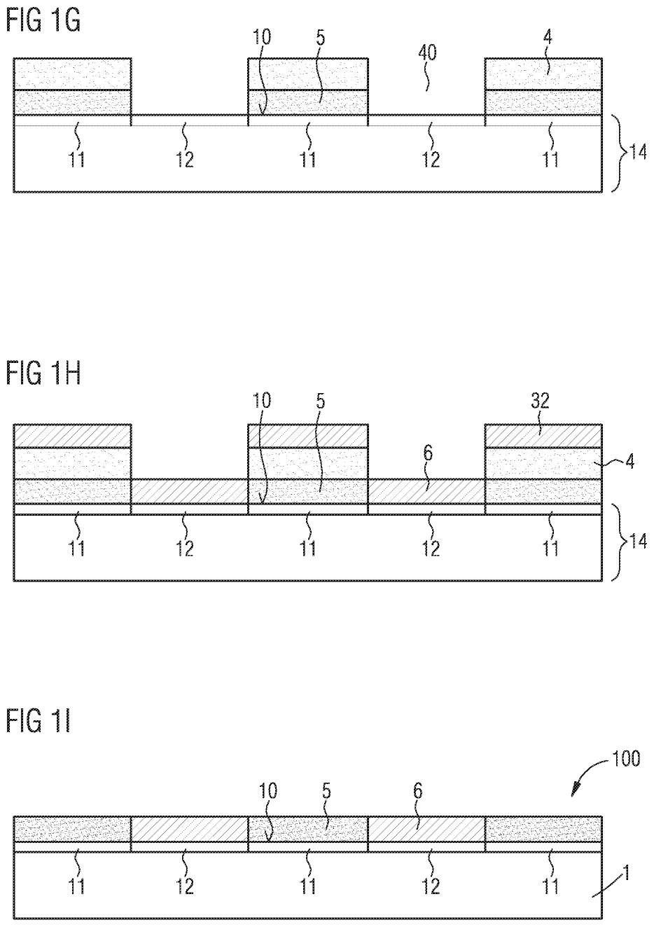

FIGS. 1A to 1F show a first exemplary embodiment of a method of manufacturing an optoelectronic semiconductor device.

In the position of FIG. 1A a semiconductor layer sequence 14 is provided, for example, in wafer compound. The semiconductor layer sequence 14 comprises a radiation side 10 with a plurality of illumination areas 11, 12. The semiconductor layer sequence 14 is, for example, an AlInGaN-based semiconductor layer sequence which generates light in the blue spectral range during normal operation. At the latest after completion of the semiconductor device, the illumination areas 11, 12 can be controlled individually and independently of each other in the intended operation, so that they can emit electromagnetic radiation individually and independently of each other.

A first photostructurable photo layer 2 is applied to the radiation side 10. The photo layer 2 consists, for example, of a photostructurable silicone. The photostructurable silicone was, for example, distributed on the radiation side 10 using a spin-coating process.

In the position shown in FIG. 1B, the first photo layer 2 is structured. In particular, holes 20 are formed in the first photo layer 2 in the area of first illumination areas 11. This was done, for example, by exposing the first photo layer 2 using a corresponding mask and then removing the remaining soluble regions.

FIG. 1B shows that the holes 20 in the first photo layer 2 have approximately the same lateral dimensions as the first illumination areas 11.

FIG. 1C shows a position of the method in which a first converter material 31 is applied to the radiation side 10. The first converter material 31 is applied to the first illumination areas 11, especially in the area of the holes 20, where it forms individual first converter elements 5. In addition, the first converter material 31 is also applied to the remaining regions of the first photo layer 2. The first converter material 31 was applied, for example, by means of a spray process. After applying the first converter material 31, it can be cured.

The first converter material 31 comprises, for example, particles of a yellow phosphor, such as YAG:Ce, which are embedded in a matrix material, for example silicone.

In the position shown in FIG. 1D, the first converter material 31 is removed from the regions outside the first illumination areas 11, in particular from the remaining regions of the first photo layer 2. This was done, for example, by grinding back the first converter material 31 or by a lift-off process.

In the position shown in FIG. 1E, the first photo layer 2 is removed from the radiation side 10. For example, the remaining components of the first photo layer 2 were removed using a solvent.

As shown in FIG. 1E, after the removal of the first photo layer 2, individual first converter elements 5 of the first converter material 31 remain. Each first converter element 5 is uniquely assigned to a first illumination area 11.

In the position shown in FIG. 1F, a second photo layer 4 is applied to the radiation side 10 and in particular also to the first converter elements 5. The second photo layer 4 may be made of the same material as the first photo layer 2.

In the position of the method shown in FIG. 1G, the second photo layer 4 is again photostructured. In this case, holes 40 are formed in the region of second illumination areas 12, which are different from the first illumination areas 11. The lateral expansions of holes 40 essentially correspond again to the lateral expansions of the second illumination areas 12. The second photo layer 4 remains only on the first converter elements 5.

In the position shown in FIG. 1H, a second converter material 32 is applied to the radiation side 10. The second converter material 32 fills up the holes 40 and forms second converter elements 6 in the region of the second illumination areas 12. The second converter material 32 comprises, for example, particles of a red phosphor, such as alkaline earth silicon nitride doped with rare earths and/or alkaline earth aluminum silicon nitride doped with rare earths, which are embedded in a matrix material, for example, of silicone. After applying the second converter material 32, it can be cured.

In the position of the method shown in FIG. 1I, the residues of the second photo layer 4 remaining after structuring and the parts of the second converter material 32 on top of it are detached from radiation side 10. What remains is an optoelectronic semiconductor device 100 with a semiconductor chip 1 which has on its radiation side 10 first converter elements 5 and second converter elements 6. The semiconductor chip 1, for example, was created by separation from the semiconductor layer sequence 14. The second converter elements 6 are uniquely assigned to the second illumination areas 12. In the lateral direction, parallel to the main direction of extension of the semiconductor chip 1, the first converter elements 5 directly adjoin the second converter elements 6.

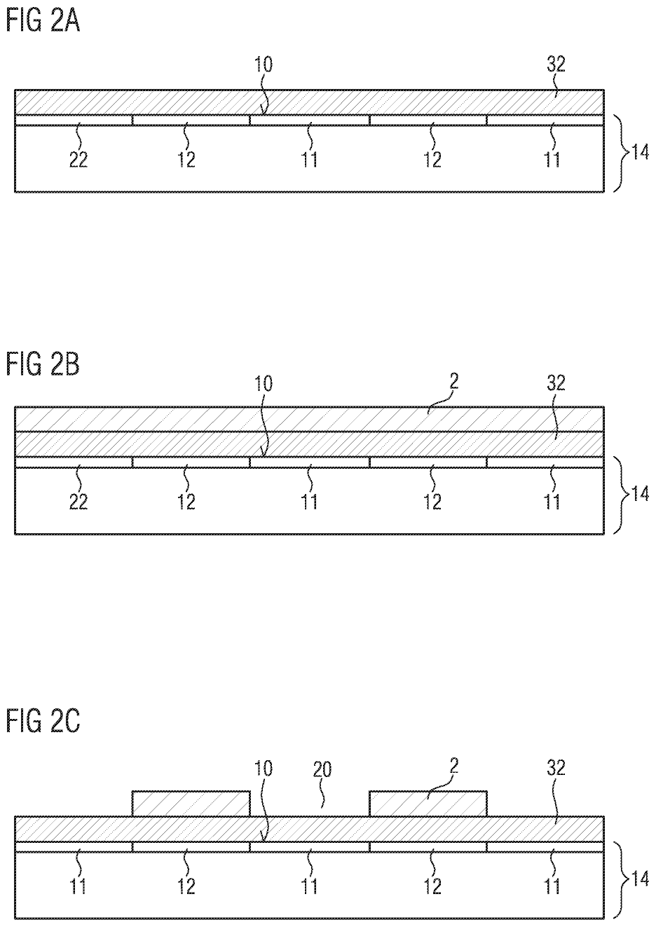

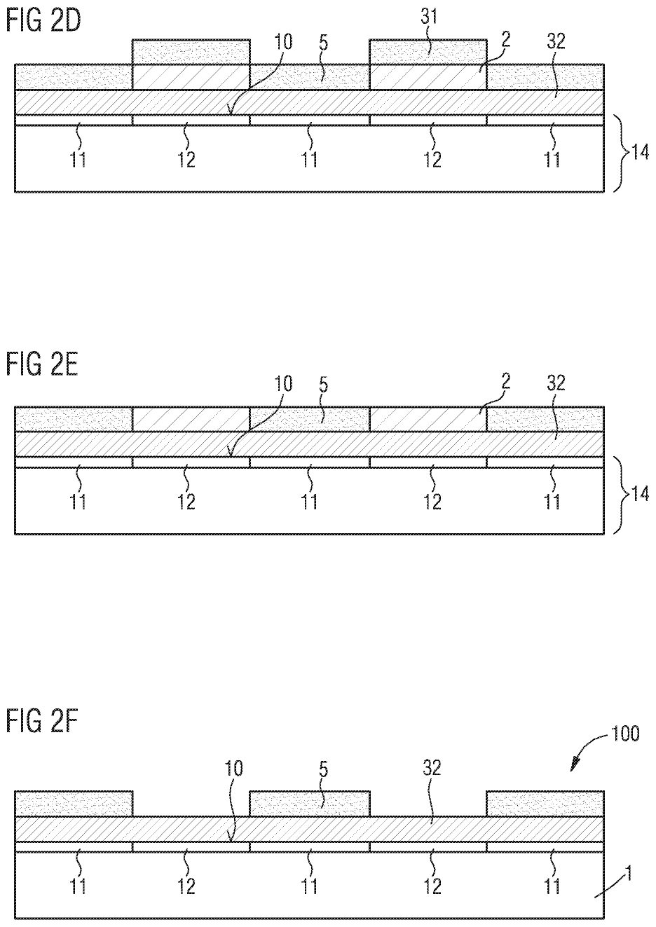

FIGS. 2A to 2F show a second exemplary embodiment of the method of manufacturing an optoelectronic semiconductor device.

In the position of FIG. 2A, a second converter material 32 in the form of a simply-connected layer is applied to a semiconductor layer sequence 14, which is formed like the semiconductor layer sequence of the first exemplary embodiment. The layer of the second converter material 32 covers a large number of first illumination areas 11 and second illumination areas 12. The material composition of the second converter material 32 is, for example, chosen as in the first exemplary embodiment.

In the position shown in FIG. 2B, a photostructurable first photo layer 2 is applied to the layer of the second converter material 32. The first photo layer 2 also covers a number of first 11 and second 12 illumination areas. The material of the first photo layer 2, for example, is chosen as in the first exemplary embodiment.

FIG. 2C shows a position of the method in which the first photo layer 2 is photostructured. In the region of the first illumination areas 11, holes 20 are formed in the first photo layer 2.

In the position shown in FIG. 2D, a first converter material 31 is applied to the holes 20 and to the remnants of the first photo layer 2, wherein the first converter material 31 can again be selected as in the first exemplary embodiment. The first converter material 31 completely fills up the holes 20 in the region of the first illumination areas 11 and forms there first converter elements 5.

In the position of FIG. 2E, for example, the first converter material 31 has been removed by a grinding process in the region of the first photo layer 2.

FIG. 2F shows a position after the remnants of the first photo layer 2 have also been removed in the region of the second illumination areas 12. What remains, possibly still after a separation process, is an optoelectronic semiconductor device 100, the radiation side 10 of which is covered by a simply-connected layer of the second converter material 32. In the region of the first illumination areas 11, first converter elements 5 are additionally applied to the layer of the second converter material 32.

When the semiconductor device 100 is operated as intended, the semiconductor chip 1 emits light in the blue spectral range. This light is partially converted by the layer of the second converter material 32 after leaving the radiation side 10, so that altogether cold white light leaves the layer of the first converter material 32. In the area of the first illumination areas 11, this cold white light is partially further converted by the first converter elements 5, so that in the region of the first illumination areas 11 warm white light emerges from the semiconductor device 100.

Since the illumination areas 11, 12 can preferably be controlled individually and independently of each other, the color temperature of the emitted light can be adjusted continuously by selecting the controlled first illumination areas 11 and second illumination areas 12.

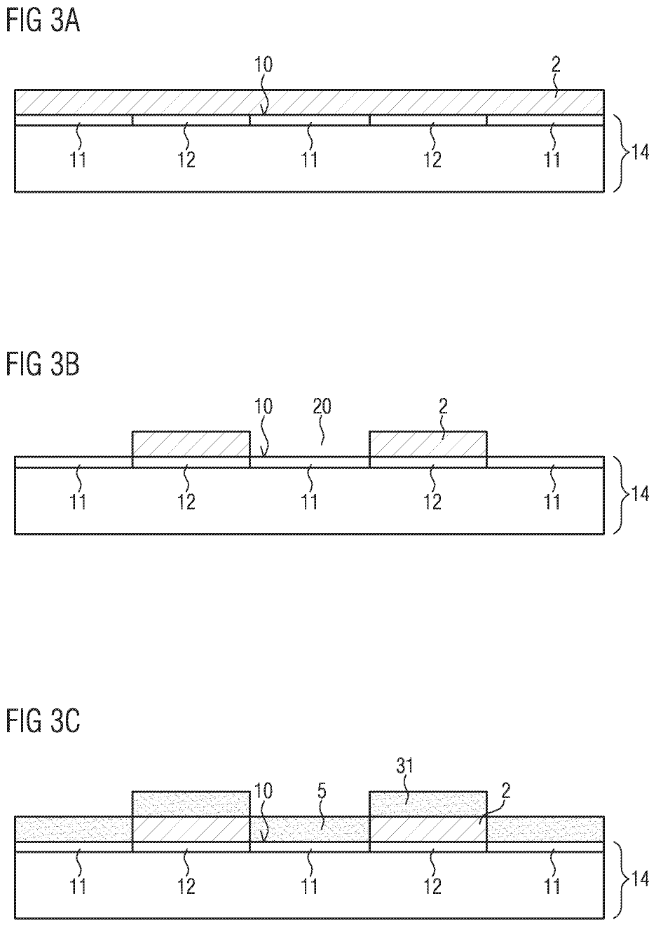

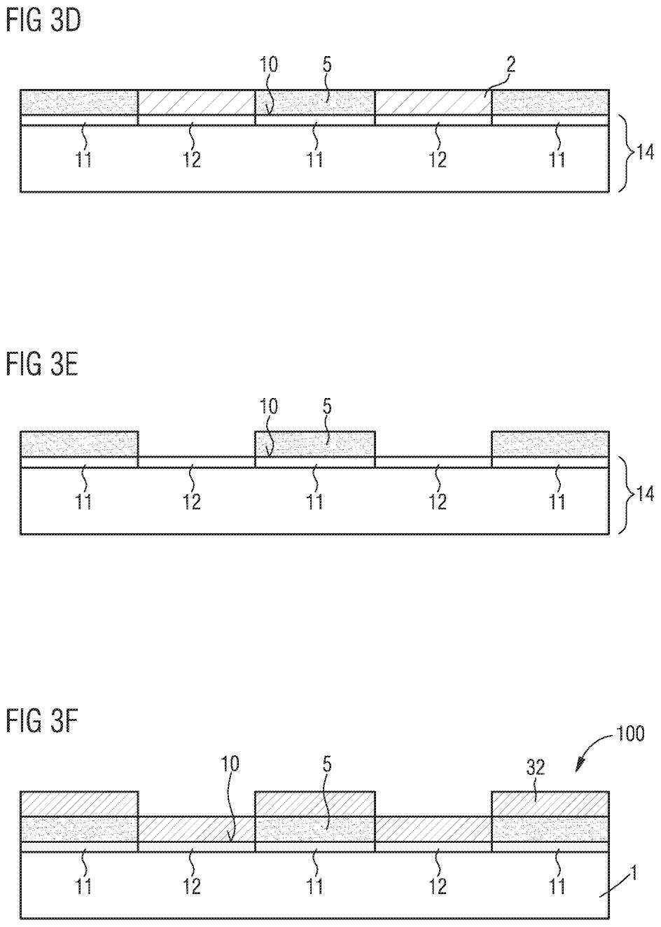

FIGS. 3A to 3F show a third exemplary embodiment of the method of manufacturing a semiconductor device.

The positions shown in FIGS. 3A to 3E correspond to the positions shown in FIGS. 1A to 1E.

In the position shown in FIG. 3F, a second converter material 32 is applied directly to the first converter elements 5 and the exposed second illumination areas 12. In the region of the second illumination areas 12, the second converter material 32 lies directly on the radiation side 10. In the region of the first illumination areas 11 the second converter material 32 covers the first converter elements 5 and is in direct contact with the first converter elements 5.

FIG. 3F shows an exemplary embodiment of a finished optoelectronic semiconductor device 100. The second illumination areas 12 are only covered by the second converter material 32, whereas the first illumination areas 11 are covered by the first converter elements 5 and in each case a layer of the second converter material 32. The light emerging from the semiconductor device 100 in the region of the second illumination areas 12 therefore has a different color temperature than the light emerging from the semiconductor device 100 in the region of the first illumination areas 11.

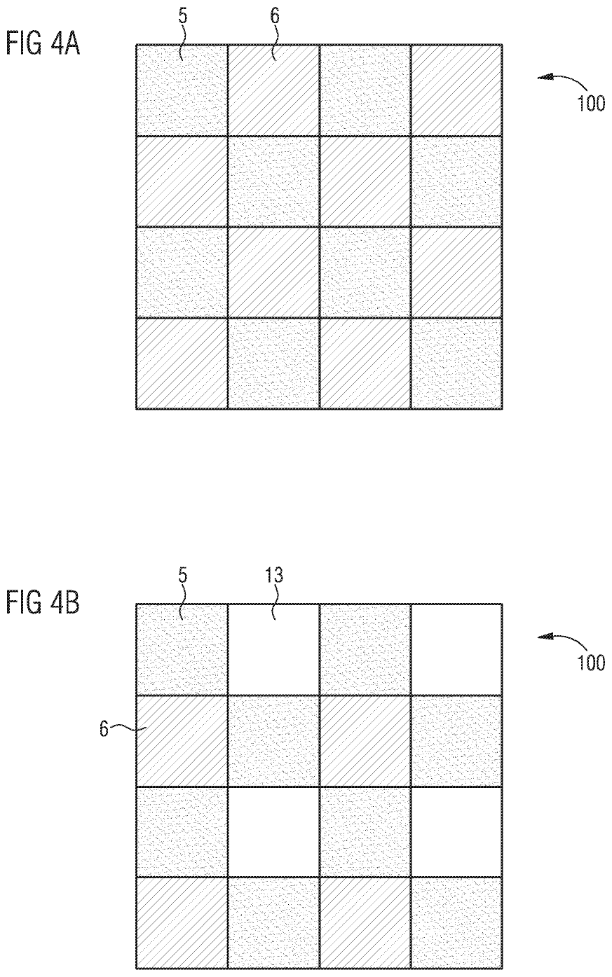

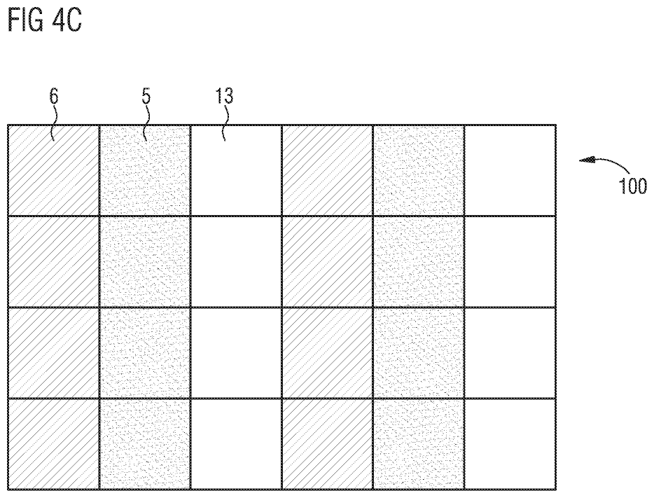

FIGS. 4A to 4C show different exemplary embodiments of an optoelectronic semiconductor device 100 in top view of the radiation side 10.

In FIG. 4A, the entire radiation side 10 is covered by first converter elements 5 and second converter elements 6, which are directly adjacent to each other in the lateral direction, parallel to the radiation side 10. The converter elements 5, 6 each have square basic shapes like the associated illumination areas 11, 12 and are distributed and arranged in a chessboard pattern. The first converter elements 5 comprise, for example, a yellow phosphor, the second converter elements 6 comprise, for example, a red phosphor. In the region of the first converter elements 5, for example, cold white light emerges from the semiconductor device 100, while in the region of the second converter elements 6, for example, warm white light emerges from the semiconductor device 100.

In the exemplary embodiment of FIG. 4B, the radiation side 10 is not completely covered by converter elements 5, 6. Rather, third illumination areas 13 of radiation side 10 are left free of converter elements 5, 6. Unconverted blue radiation then emerges from the semiconductor device 100 via the third illumination areas 13. In the present case, the converter elements 5, 6 are set up, for example, for full conversion of the blue radiation emerging from radiation side 10. For example, the first converter elements 5 convert the blue light into green light. The second converter elements 6 convert the blue light into red light, for example. In total, the exposed third illumination areas 13, the first converter elements 5 and the second converter elements 6 are distributed in such a way that a Bayer matrix is formed. The semiconductor device 100, for example, is an RGB-LED.

In the exemplary embodiment of FIG. 4C, the radiation side 10 again has first illumination areas 11, second illumination areas 12 and third illumination areas 13, wherein the first and second illumination areas 11, 12 are covered by first converter elements 5 and second converter elements 6, which are configured like the converter elements of FIG. 4B, for example.

In FIG. 4C, the first illumination areas 11, the second illumination areas 12 and the third illumination areas 13 are each arranged in stripes, so that an RGB striped pixel arrangement as in LCD displays is realized.

The invention is not limited to the description based on the exemplary embodiments. Rather, the invention comprises every new feature as well as every combination of features, which in particular includes every combination of features in the claims, even if these features or this combination itself is not explicitly stated in the claims or exemplary embodiments.

1-18. (canceled)

19. A method for manufacturing an optoelectronic semiconductor device, the method comprising:
A) providing a semiconductor layer sequence, the semiconductor layer sequence having a radiation side with a plurality of illumination areas;
B) applying a photostructurable first photo layer on the radiation side;
C) photostructuring the first photo layer, wherein holes are formed in the first photo layer in regions of first illumination areas;
D) applying a first converter material to the structured first photo layer, wherein the first converter material partially or completely fills the holes, thereby forming first converter elements in the holes, the first converter elements covering the associated first illumination areas;
E) removing the first photo layer; and
F) applying a second converter material to the radiation side at least in regions of second illumination areas, the second illumination areas being different from the first illumination areas.

20. The method according to claim 19, wherein the first converter elements are in direct contact with the second converter material after steps A) to F).

21. The method according to claim 19, wherein the first photo layer comprises a photostructurable silicone.

22. The method according to claim 19, further comprising removing the first converter material from regions laterally adjacent to the holes before or during step E).

23. The method according to claim 19, wherein step F) is carried out after steps A) to E).

24. The method according to claim 23, wherein the second converter material is applied to a plurality of illumination areas, thereby also covering the first illumination areas which are already covered with the first converter elements.

25. The method according to claim 24, wherein applying the second converter material comprises directly applying the second converter material to the first converter elements in the regions of the first illumination areas.

26. The method according to claim 23, wherein applying the second converter material comprises:
applying a photostructurable second photo layer to the radiation side;
photostructuring the second photo layer such that holes are created in the regions of the second illumination areas; and
applying the second converter material to the structured second photo layer,
wherein the second converter material partially or completely fills the holes, thereby forming second converter elements in the holes, the second converter elements covering the associated second illumination areas, and
wherein the second converter elements directly adjoin the first converter elements.

27. The method according to claim 19, wherein step F) is carried out before steps B) to E).

28. The method according to claim 27, wherein applying the second converter material comprises applying the second converter material as a simply-connected layer covering the first illumination areas and the second illumination areas.

29. The method according to claim 19, wherein the radiation side comprises third illumination areas, and wherein the third illumination areas are kept free from the first converter material and the second converter material.

30. An optoelectronic semiconductor device comprising:
a pixelated semiconductor chip, wherein the semiconductor chip has a radiation side with a plurality of illumination areas;
first converter elements, wherein first illumination areas are covered by the first converter elements made of a first converter material, wherein a first converter element is uniquely assigned to each of the first illumination areas; and
a second converter material covering second illumination areas, wherein the second converter material is different from the first converter material, wherein the second illumination areas are different from the first illumination areas,
wherein the second converter material is directly adjoining the first converter elements, and
wherein each of the first converter material and the second converter material comprises a matrix material in which phosphor particles are distributed.

31. The semiconductor device according to claim 30,
wherein the second converter material is a simple connect layer over a plurality of first illumination areas and second illumination areas,
wherein, in regions of the first illumination areas, the layer of the second converter material is arranged between the semiconductor chip and the first converter elements.

32. The semiconductor device according to claim 30, wherein the second converter material also covers the first converter elements so that the first converter elements are arranged between the semiconductor chip and the second converter material.

33. The semiconductor device according to claim 30,
wherein the second illumination areas are covered by second converter elements made of the second converter material, and
wherein a second converter element is uniquely assigned to each of the second illumination areas.

34. The semiconductor device according to claim 30,
wherein the semiconductor chip is configured to emit radiation of a first wavelength range, and
wherein the first converter material and the second converter material are selected such that radiation emerging from the semiconductor device in regions of the first illumination areas is warm white light and radiation emerging from regions of the second illumination areas from the semiconductor device is cold white light.

35. The semiconductor device according to claim 30,
wherein the semiconductor chip is configured to emit blue light,
wherein the first converter material is configured to convert blue light into green light,
wherein the second converter material is configured to convert blue light into red light.

36. The semiconductor device according to claim 30, wherein the semiconductor device has a radiation surface with a Bayer matrix.

37. A method of manufacturing an optoelectronic semiconductor device, the method comprising:
A) providing a semiconductor layer sequence, the semiconductor layer sequence having a radiation side with a plurality of illumination areas;
B) applying a photostructurable first photo layer on the radiation side;
C) photostructuring the first photo layer, wherein holes are formed in the first photo layer in regions of first illumination areas;
D) applying a first converter material to the structured first photo layer, wherein the first converter material partially or completely fills the holes, thereby forming first converter elements in the holes, the first converter elements covering the associated first illumination areas;
E) removing the first photo layer;
F) applying a second converter material to the radiation side at least in regions of second illumination areas, the second illumination areas being different from the first illumination areas,
wherein, after steps A) to F), the first converter elements are in direct contact with the second converter material,
wherein, after steps E) and F), the semiconductor layer sequence is separated into a plurality of pixelated semiconductor chips, each semiconductor chip comprising a part of the semiconductor layer sequence, an active layer and a part of the radiation side including first and second illumination areas, and
wherein the active layer of a semiconductor chip is formed contiguously.
